(19) United States
(12) Patent Application Publication
(10) Pub. No.: US 2024/0079535 A1
(43) Pub. Date: Mar. 7, 2024

(54) COLOR CONVERSION SUBSTRATE AND DISPLAY DEVICE INCLUDING THE SAME

(71) Applicant: Samsung Display Co., LTD., Yongin-si (KR)

(72) Inventors: SUNGJAE MOON, Yongin-si (KR); SEUNGSOO BAEK, Yongin-si (KR)

(73) Assignee: Samsung Display Co., LTD., Yongin-si (KR)

(21) Appl. No.: 18/343,890

(22) Filed: Jun. 29, 2023

(30) Foreign Application Priority Data
Sep. 7, 2022 (KR) 10-2022-0113314

(51) Int. Cl. H01L 33/50; H01L 33/58

(52) U.S. Cl. CPC H01L 33/505; H01L 33/58

(57) ABSTRACT

A color conversion substrate includes a base substrate including a display area and a peripheral area disposed adjacent to the display area and including a first area and a second area surrounding a first area, a color filter layer disposed in a display area under a base substrate, and a light blocking member disposed in a peripheral area under a base substrate and including a first blocking layer, a second blocking layer, and a third light blocking layer overlapping each other in a first direction which is a thickness direction of a base substrate in a second area. Two of the first to third light blocking layers include an opening located in a first area, and another one of the first to third light blocking layers covers the openings in a first area.

### CROSS-REFERENCE TO RELATED APPLICATION(S)

This application claims priority to and benefits of Korean Patent Application No. 10-2022-0113314 under 35 U.S.C. § 119, filed on Sep. 7, 2022, in the Korean Intellectual Property Office, the entire contents of which are incorporated herein by reference.

### BACKGROUND

### 1. Technical Field

The disclosure relates to a color conversion substrate and a display device including the color conversion substrate.

### 2. Description of the Related Art

A flat panel display device is used as a display device replacing a cathode ray tube display device due to characteristics such as light weight and a thin shape. Representative examples of such a flat panel display include a liquid crystal display and an organic light emitting display.

Recently, in order to improve a display quality, a display device including a display substrate including multiple pixels and a color conversion substrate including a color filter and a color conversion part has been proposed.

Accordingly, when the display substrate and the color conversion substrate are bonded, it is required to determine whether there is an alignment error between the display substrate and the color conversion substrate.

### SUMMARY

Embodiments provide a color conversion substrate capable of reducing a visibility of an align key by external light.

Embodiments provide a display device capable of reducing a visibility of an align key by external light.

A color conversion substrate according to an embodiment may include a base substrate including a display area, and a peripheral area disposed adjacent to the display area and including a first area and a second area surrounding the first area, a color filter layer disposed in the display area under the base substrate, and a light blocking member disposed in the peripheral area under the base substrate and including a first light blocking layer, a second light blocking layer, and a third light blocking layer overlapping each other in a first direction which is a thickness direction of the base substrate in the second area. Two of the first to third light blocking layers may include an opening in the first area, and another one of the first to third light blocking layers may cover the opening in the first area.

In an embodiment, the color filter layer may include a red color filter that selectively transmits red light, a green color filter that selectively transmits green light, and a blue color filter that selectively transmits blue light, the first light blocking layer and the blue color filter may include a same material, the second light blocking layer and the red color filter may include a same material, and the third light blocking layer and the green color filter may include a same material.

In an embodiment, each of the first light blocking layer and the third light blocking layer may include the opening, and the second light blocking layer may cover the openings in the first area.

In an embodiment, each of the second light blocking layer and the third light blocking layer may include the opening, and the first light blocking layer may cover the openings in the first area.

In an embodiment, each of the first light blocking layer and the second light blocking layer may include the opening, and the third light blocking layer may cover the openings in the first area.

In an embodiment, the opening may include a first sub opening disposed on one of the first to third light blocking layers including the opening, and a second sub opening disposed on another one of the first to third light blocking layers including the opening.

In an embodiment, in a cross-sectional view, a width of the first sub opening in a second direction perpendicular to the first direction may be less than a width of the second sub opening in the second direction.

In an embodiment, the color conversion substrate may further include a refraction layer covering the color filter layer and the light blocking member, a first capping layer disposed on a lower surface of the refraction layer, and a second capping layer disposed on a lower surface of the first capping layer in the peripheral area.

A color conversion substrate according to another embodiment may include a base substrate including a display area, and a peripheral area disposed adjacent to the display area and including a first area and a second area surrounding the first area, a color filter layer disposed in the display area under the base substrate, and a light blocking member disposed in the peripheral area under the base substrate and including a first light blocking layer, a second light blocking layer, and a third light blocking layer overlapping each other in a first direction which is a thickness direction of the base substrate in the second area. One of the first to third light blocking layers may include an opening in the first area, and at least another one of the first to third light blocking layers may cover the opening in the first area.

In an embodiment, the color filter layer may include a red color filter that selectively transmits red light, a green color filter that selectively transmits green light, and a blue color filter that selectively transmits blue light, the first light blocking layer and the blue color filter may include a same material, the second light blocking layer and the red color filter may include a same material, and the third light blocking layer and the green color filter may include a same material.

In an embodiment, the first light blocking layer may include the opening, and the second light blocking layer and the third light blocking layer may overlap each other in the first direction in the first area and may cover the opening.

In an embodiment, the second light blocking layer may include the opening, and the first light blocking layer and the third light blocking layer may overlap each other in the first direction in the first area and may cover the opening.

In an embodiment, the third light blocking layer may include the opening, and the first light blocking layer and the second light blocking layer may overlap each other in the first direction in the first area and may cover the opening.

A display device according to an embodiment may include a display substrate including a first base substrate and pixels disposed on the first base substrate, a color conversion substrate facing the display substrate, and a sealing member bonding the display substrate and the color conversion substrate. The color conversion substrate may include a base substrate including a display area, and a peripheral area disposed adjacent to the display area and including a first area and a second area surrounding the first area, a color filter layer disposed in the display area under the base substrate, and a light blocking member disposed in the peripheral area under the base substrate and including a first light blocking layer, a second light blocking layer, and a third light blocking layer overlapping each other in a first direction which is a thickness direction of the second base substrate in the second area. At least one of the first to third light blocking layers may include an opening in the first area, and at least another one of the first to third light blocking layers may cover the opening in the first area.

In an embodiment, the color filter layer may include a red color filter that selectively transmits red light, a green color filter that selectively transmits green light, and a blue color filter that selectively transmits blue light, the first light blocking layer and the blue color filter may include a same material, the second light blocking layer and the red color filter may include a same material, and the third light blocking layer and the green color filter may include a same material.

In an embodiment, the display substrate may further include an align key disposed on the first base substrate and overlapping the opening in the first direction.

In an embodiment, in a cross-sectional view, a width of the opening in a second direction perpendicular to the first direction may be greater than a width of the align key in the second direction.

In an embodiment, the opening and the align key may be spaced apart from the sealing member in a plan view.

In an embodiment, the align key may include a metal.

In an embodiment, the display device may further include a filling layer disposed between the display substrate and the color conversion substrate.

The display device according to embodiments may include a display substrate and a color conversion substrate. The color conversion substrate may include a light blocking member disposed in a peripheral area and including a first light blocking layer, a second light blocking layer, and a third light blocking layer. At least one of the first to third light blocking layers may include an opening, and at least another one of the first to third light blocking layers may cover the opening. Accordingly, visibility of align key due to external light through the opening may be reduced. Therefore, after the display substrate and the color conversion substrate are bonded, it is possible to prevent the align key from being recognized through the opening. Accordingly, a quality of the display device may be improved.

However, embodiments of the disclosure are not limited to those set forth herein. The above and other embodiments will become more apparent to one of ordinary skill in the art to which the disclosure pertains by referencing the detailed description of the disclosure given below.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a schematic cross-sectional view taken along line I-I′ of FIG. 1.

FIG. 3 is a schematic cross-sectional view illustrating a display device of FIG. 1 according to an embodiment.

FIG. 4 is an enlarged view illustrating area ‘A’ of FIG. 3.

FIGS. 5 to 8 are schematic cross-sectional views illustrating a method of manufacturing a color conversion substrate included in the display device of FIG. 3.

FIGS. 9 and 10 are schematic cross-sectional views illustrating a display device according to an embodiment.

FIGS. 11 and 12 are schematic cross-sectional views illustrating a display device according to an embodiment.

FIGS. 13 and 14 are schematic cross-sectional views illustrating a display device according to an embodiment.

FIGS. 15 and 16 are schematic cross-sectional views illustrating a display device according to an embodiment.

FIGS. 17 and 18 are schematic cross-sectional views illustrating a display device according to an embodiment.

### DETAILED DESCRIPTION OF THE EMBODIMENTS

The disclosure now will be described more fully hereinafter with reference to the accompanying drawings, in which various embodiments are shown. The embodiments may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

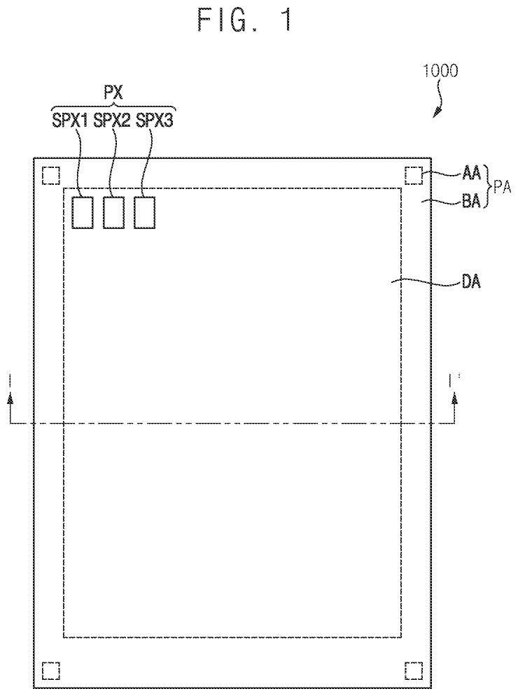

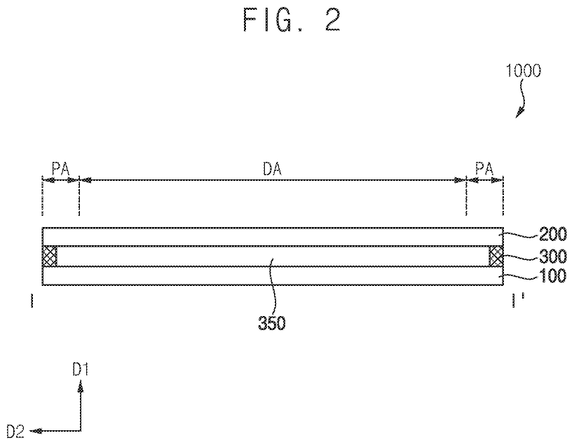

FIG. 1 is a plan view illustrating a display device according to an embodiment. FIG. 2 is a schematic cross-sectional view taken along line I-I′ of FIG. 1.

Referring to FIGS. 1 and 2, the display device 1000 may include a first substrate 100, a second substrate 200, a sealing member 300 and a filling layer 350. The second substrate 200 may face the first substrate 100 and be located in the first direction D1 which is a front direction of the display device 1000 from the first substrate 100.

The first substrate 100 may include multiple pixels PX and may be referred to as a display substrate. The second substrate 200 may include a color conversion part and may be referred to as a color conversion substrate. The color conversion part may be disposed in the display area DA and may convert a wavelength of light generated from a light emitting device of the first substrate 100. The second substrate 200 may further include a color filter layer that transmits light of a specific color.

The sealing member 300 may bond the first substrate 100 and the second substrate 200. The sealing member 300 may be disposed in a peripheral area PA between the first substrate 100 and the second substrate 200. For example, the sealing member 300 may be disposed in the peripheral area PA between the first substrate 100 and the second substrate 200 and surround a display area DA in a plan view. In an embodiment, the sealing member 300 may have a hollow rectangular shape in a plan view. However, the disclosure is not necessarily limited thereto, and the sealing member 300 may have various planar shapes depending on the planar shape of the first substrate 100 or the second substrate 200. For example, in case that the first substrate 100 or the second substrate 200 has a shape such as a triangle, a rhombus, a polygon, a circle, or an ellipse in a plan view, the sealing member 300 may have a shape such as a hollow triangle, a hollow diamond, a hollow polygon, a hollow circle, or a hollow ellipse in a plan view.

In an embodiment, the filling layer 350 may be disposed between the first substrate 100 and the second substrate 200. For example, the filling layer 350 may act as a buffer against external pressure applied to the display device 1000. For example, the filling layer 350 may maintain a gap between the first substrate 100 and the second substrate 200. In another embodiment, the filling layer 350 may be omitted.

The display device 1000 (e.g., each of the first substrate 100 and the second substrate 200) may include the display area DA and the peripheral area PA. In an embodiment, the display area DA may display an image and the peripheral area PA may be located adjacent to the display area DA. For example, the peripheral area PA may surround the display area DA in a plan view. In an embodiment, the peripheral area PA may include a first area AA and a second area BA.

An opening defined by light blocking layers of the second substrate 200 may be disposed in the first area AA. Also, the first area AA may overlap am align key of the first substrate 100 in the first direction D1. Accordingly, it may be determined whether there is an alignment error between the first substrate 100 and the second substrate 200 from the first area AA. The first area AA may be referred to as an alignment area.

The second area BA may be located adjacent to the first area AA. For example, the second area BA may surround the first area AA. In the second area BA, first to third light blocking layers of the second substrate 200 may overlap each other in the first direction D1. Accordingly, a light traveling in the first direction D1 may be effectively blocked. The second area BA may be referred to as a light blocking area.

In an embodiment, the first area AA may be disposed at four corners of the display device 1000. Although FIG. 1 illustrates that the first areas AA are disposed at each of the four corners of the display device 1000, the disclosure is not necessarily limited thereto. In another embodiment, the first area AA may be disposed in various locations and in various numbers as long as it is within the peripheral area PA. For example, the first area AA may be disposed at two corners of the display device 1000, diagonally from each other, or disposed on a same side of the display device 1000.

Multiple pixels PX may be disposed in the display area DA. Each of the pixels PX may include a driving device and a light emitting device. As the pixels PX emits light, the display area DA may display an image.

Each of the pixels PX may include a first sub-pixel SPX1, a second sub-pixel SPX2, and a third sub-pixel SPX3. Each of the sub-pixels SPX1, SPX2, and SPX3 may include a driving device and a light emitting device. The driving device may include at least one thin film transistor and at least one capacitor. The light emitting device may generate light according to a driving signal. For example, the light emitting device may be an inorganic light emitting diode or an organic light emitting diode.

In an embodiment, the first sub-pixel SPX1 may be a red sub-pixel emitting red light, the second sub-pixel SPX2 may be a green sub-pixel emitting green light, and the third sub-pixel SPX3 may be a blue sub-pixel emitting blue light. However, the color of light emitted from the first to third sub-pixels SPX1, SPX2, and SPX3 is not limited thereto. Also, although each of the pixels PX is illustrated as including three sub-pixels, it is not necessarily limited thereto. For example, each of the pixels PX may further include a fourth sub-pixel emitting white light.

The display device 1000 may include drivers disposed in the peripheral area PA. For example, the drivers may include a gate driver and a data driver. The drivers may be electrically connected to the pixels PX. The drivers may provide signals and voltages for emitting light from the pixels PX.

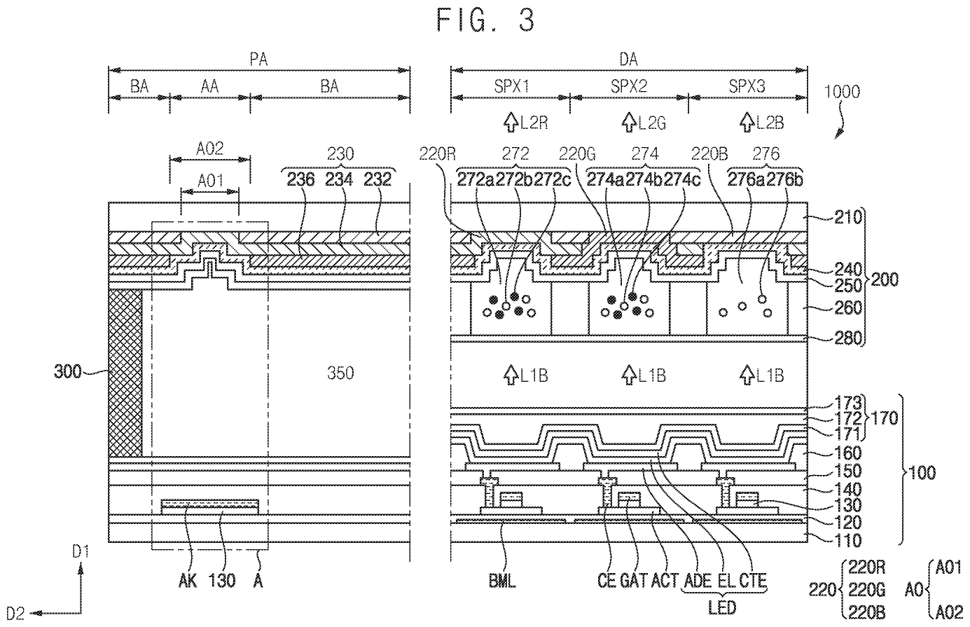

FIG. 3 is a schematic cross-sectional view illustrating a display device of FIG. 1 according to an embodiment.

Referring to FIGS. 1 to 3, the first substrate 100 may include a first base substrate 110, a buffer layer 120, a lower metal pattern BML, an active pattern ACT, a gate insulating layer 130, a gate electrode GAT, a first interlayer insulating layer 140, a connection electrode CE, a second interlayer insulating layer 150, an align key AK, a pixel electrode ADE, a pixel defining layer 160, a light emitting layer EL, a common electrode CTE, and an encapsulation layer 170.

The first base substrate 110 may include a transparent material or an opaque material. In an embodiment, examples of a material that can be used as the first base substrate 110 may include glass, quartz, plastic, or the like. These may be used alone or in combination with each other. The first base substrate 110 may be formed as a single layer or as multiple layers.

The lower metal pattern BML may be disposed in the display area DA on the first base substrate 110. In an embodiment, the lower metal pattern BML may be formed of a metal, an alloy, a conductive metal oxide, a transparent conductive material, or the like. Examples of materials that can be used as the lower metal pattern BML may include silver (Ag), alloys containing silver, molybdenum (Mo), alloys containing molybdenum, aluminum (Al), alloys containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Also, the lower metal pattern BML may be formed as a single layer or as multiple layers.

The buffer layer 120 may be disposed on the first base substrate 110 and cover the lower metal pattern BML. The buffer layer 120 may prevent impurities such as oxygen and moisture from diffusing onto the first base substrate 110 through the first base substrate 110. The buffer layer 120 may include an inorganic insulating material such as a silicon compound or a metal oxide. Examples of the inorganic insulating material may include silicon oxide (SiO), silicon nitride (SiN), silicon oxynitride (SiON), silicon oxycarbide (SiOC), silicon carbonitride (SiCN), aluminum oxide (AlO), and aluminum nitride. (AlN), tantalum oxide (TaO), hafnium oxide (HfO), zirconium oxide (ZrO), titanium oxide (TiO), or the like. These may be used alone or in combination with each other. The buffer layer 120 may have a single-layer structure or a multi-layer structure including multiple insulating layers.

The active pattern ACT may be disposed on the buffer layer 120. In an embodiment, the active pattern ACT may be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may include IGZO (InGaZnO) and ITZO (InSnZnO). The oxide semiconductor material may also include indium (In), gallium (Ga), tin (Sn), zirconium (Zr), vanadium (V), hafnium (Hf), cadmium (Cd), germanium (Ge), chromium (Cr)), titanium (Ti), and zinc (Zn). These may be used alone or in combination with each other.

The gate insulating layer 130 may be disposed on the active pattern ACT. In an embodiment, the gate insulating layer 130 may be formed of an insulating material. Examples of an insulating material that can be used as the gate insulating layer 130 may include silicon oxide, silicon nitride, and silicon oxynitride. These may be used alone or in combination with each other. In an embodiment, as shown in FIG. 3, the gate insulating layer 130 may be disposed on the active pattern ACT in a pattern form. However, the disclosure is not necessarily limited thereto, and in another embodiment, the gate insulating layer 130 may be entirely formed on the buffer layer 120 to cover the active pattern ACT.

The gate electrode GAT may be disposed on the gate insulating layer 130. In an embodiment, the gate electrode GAT may be formed of a metal, an alloy, a conductive metal oxide, a transparent conductive material, or the like. Examples of materials that can be used as the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The first interlayer insulating layer 140 may be disposed on the buffer layer 120 and the gate insulating layer 130. The first interlayer insulating layer 140 may cover the gate electrode GAT. A contact hole may be defined in the first interlayer insulating layer 140. The contact hole may expose a portion of the active pattern ACT. In an embodiment, the first interlayer insulating layer 140 may be formed of an inorganic insulating material. Examples of the inorganic insulating materials that can be used as the first interlayer insulating layer 140 may include silicon oxide, silicon nitride, and silicon oxynitride. These may be used alone or in combination with each other.

The connection electrode CE may be disposed on the first interlayer insulating layer 140. The connection electrode CE may contact the active pattern ACT through the contact hole. In an embodiment, the connection electrode CE may be formed of a metal, an alloy, a conductive metal oxide, a transparent conductive material, or the like. Examples of materials that can be used as the connection electrode CE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second interlayer insulating layer 150 may be disposed on the first interlayer insulating layer 140. The second interlayer insulating layer 150 may cover the connection electrode CE. In an embodiment, as shown in FIG. 3, the second interlayer insulating layer 150 may be a single layer. However, the disclosure is not necessarily limited thereto, and in another embodiment, the second interlayer insulating layer 150 may include multiple layers. For example, the second interlayer insulating layer 150 may include a passivation layer disposed on the first interlayer insulating layer 140 and a via insulating layer disposed on the passivation layer.

The align key AK may be disposed in the peripheral area PA on the first base substrate 110. For example, the align key AK may overlap the opening of the second substrate 200 in the first direction D1. The align key AK may be disposed to determine an alignment error between the first substrate 100 and the second substrate 200 when the first substrate 100 and the second substrate 200 are bonded.

In an embodiment, the align key AK and one of the lower metal pattern BML, the gate electrode GAT, and the connection electrode CE may include a same material. For example, the align key AK may include a metal. Examples of materials that can be used as the align key AK may include silver (Ag), alloys containing silver, molybdenum (Mo), alloys containing molybdenum, aluminum (Al), alloys containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

For example, the align key AK may be formed together with the lower metal pattern BML, the gate electrode GAT, or the connection electrode CE. In other words, the align key AK and one of the lower metal pattern BML, the gate electrode GAT, and the connection electrode CE may be formed on a same layer. For example, as shown in FIG. 3, in case that the align key AK is formed together with the gate electrode GAT, the align key AK may be disposed on the gate insulating layer 130 disposed on the buffer layer 120 in a pattern form, and covered by the first interlayer insulating layer 140. In the embodiment, the gate insulating layer 130 disposed in the peripheral area PA on the first base substrate 110 and the align key AK may have a same pattern in a plan view. In other words, a shape of the gate insulating layer 130 disposed in the peripheral area PA on the first base substrate 110 and the align key AK may be substantially the same in a plan view. However, the disclosure is not necessarily limited thereto. In another embodiment, the align key AK may be disposed on the gate insulating layer 130, and the gate insulating layer 130 may be disposed on an entire area of the buffer layer 120 and covered by the first interlayer insulating layer 140 in the peripheral area PA. In another embodiment, in case that the align key AK is formed together with the lower metal pattern BML, the align key AK may be disposed on the first base substrate 110 and covered by the buffer layer 120. In another embodiment, in case that the align key AK is formed together with the connection electrode CE, the align key AK may be disposed on the first interlayer insulating layer 140 and covered by the second interlayer insulating layer 150.

In an embodiment, the align key AK may have a cross shape in a plan view. However, the disclosure is not necessarily limited thereto, and the align key AK may have various planar shapes for determining an alignment error between the first substrate 100 and the second substrate 200, when the first substrate 100 and the second substrate 200 are bonded. For example, the align key AK may have a shape such as a polygon, a circle, an ellipse, a ‘T’ shape, or an ‘L’ shape in a plan view.

In an embodiment, the align key AK may be spaced apart from the sealing member 300 in a plan view. For example, the align key AK may be disposed in the peripheral area PA and may not overlap the sealing member 300 in the first direction D1. In other words, the align key AK may be disposed between the sealing member 300 and the display area DA in a plan view. However, the disclosure is not necessarily limited thereto, and in another embodiment, the align key AK may overlap the sealing member 300 in the first direction D1.

The pixel electrode ADE may be disposed in the display area DA on the second interlayer insulating layer 150. The pixel electrode ADE may contact the connection electrode CE through contact hole formed in the second interlayer insulating layer 150. The pixel electrode ADE may include a conductive material such as metal, alloy, conductive metal nitride, conductive metal oxide, or transparent conductive material. The pixel electrode ADE may have a single-layer structure or a multi-layer structure including multiple conductive layers.

The pixel defining layer 160 may be disposed on the second interlayer insulating layer 150. The pixel defining layer 160 may include an organic insulating material. Examples of the organic insulating material may include photoresist, polyacryl-based resin, polyimide-based resin, polyamide-based resin, siloxane-based resin, acrylic-based resin, epoxy-based resin, or the like. These may be used alone or in combination with each other. The pixel defining layer 160 may expose at least a portion of the pixel electrode ADE.

A light emitting layer EL may be disposed on the pixel electrode ADE exposed by the pixel defining layer 160. In an embodiment, the light emitting layer EL may continuously extend over the pixels in the display area DA. For example, the light emitting layer EL may be disposed on the pixel electrode ADE and the pixel defining layer 160. In another embodiment, the light emitting layer EL of a sub-pixel may be separated from the light emitting layer of an adjacent sub-pixel.

In an embodiment, the light emitting layer EL may have a multilayer structure in which multiple layers are stacked each other. For example, in case that the light emitting layer EL generates blue light, the light emitting layer EL may have a structure in which multiple blue organic light emitting layers are stacked each other. In another embodiment, the light emitting layer EL may have a multilayer structure in which multiple layers emitting light of different colors are stacked each other. For example, in case that the light emitting layer EL generates blue light, the light emitting layer EL may have a structure in which multiple blue organic light emitting layers and an organic light emitting layer emitting light of a color other than blue are stacked each other. For example, the light emitting layer EL may have a structure in which three blue organic light emitting layers and one green organic light emitting layer are stacked each other.

The common electrode CTE may be disposed on the light emitting layer EL. The common electrode CTE may include a conductive material such as a metal, an alloy, a conductive metal nitride, a conductive metal oxide, or a transparent conductive material. The common electrode CTE may have a single-layer structure or a multi-layer structure including multiple conductive layers. In an embodiment, the common electrode CTE may continuously extend over the pixels in the display area DA. The light emitting layer EL may emit light based on a voltage difference between the pixel electrode ADE and the common electrode CTE.

Accordingly, a light emitting device LED including the pixel electrode ADE, the light emitting layer EL, and the common electrode CTE may be disposed on the first substrate SUB1. Each of the first to third sub-pixels SPX1, SPX2, and SPX3 may include the light emitting device LED.

Although not shown, in another embodiment a hole control layer may be disposed between the pixel electrode ADE and the light emitting layer EL. The hole control layer may include a hole transport layer and may further include a hole injection layer. In another embodiment, an electronic control layer may be disposed between the light emitting layer EL and the common electrode CTE. The electron control layer may include an electron transport layer and may further include an electron injection layer.

The encapsulation layer 170 may be disposed on the common electrode CTE. The encapsulation layer 170 may include at least one inorganic encapsulation layer and at least one organic encapsulation layer. In an embodiment, the encapsulation layer 170 may include a first inorganic encapsulation layer 171 disposed on the common electrode CTE, an organic encapsulation layer 172 disposed on the first inorganic encapsulation layer 171, and a second inorganic encapsulation layer 173 disposed on the organic encapsulation layer 172.

The second substrate 200 may be disposed on the encapsulation layer 170 in the first direction D1. Hereinafter, the first direction D1 may be referred to as a front direction or a thickness direction.

In an embodiment, the second substrate 200 may include a second base substrate 210, a color filter layer 220, a light blocking member 230, a refraction layer 240, a first capping layer 250, a partition wall structure 260, a first color conversion part 272, a second color conversion part 274, a light transmission part 276, and a second capping layer 280.

The second base substrate 210 may include a transparent material or an opaque material. In an embodiment, examples of materials that can be used as the second base substrate 210 may include glass, quartz, plastic, or the like. These may be used alone or in combination with each other. The second base substrate 210 may be formed as a single layer or as multiple layers. The second base substrate 210 may include the aforementioned display area DA and a peripheral area PA including the first area AA and the second area BA.

The color filter layer 220 may be disposed in the display area DA under the second base substrate 210. In an embodiment, the color filter layer 220 may include a red color filter 220R, a green color filter 220G, and a blue color filter 220B. The red color filter 220R may transmit red light and block lights having colors different from the red light. The green color filter 220G may transmit green light and block lights having a different color from the green light. The blue color filter 220B may transmit blue light and block light having a different color from the blue light.

In an embodiment, the red color filter 220R may partially overlap the first color conversion part 272, the green color filter 220G may partially overlap the second color conversion part 274, and the blue color filter 220G may partially overlap the light transmission part 276 in the first direction D1.

In an embodiment, portions of the red, green, and blue color filters 220R, 220G, and 220B may overlap each other in the first direction D1. Accordingly, color mixing between adjacent sub-pixels SPX1, SPX2, and SPX3 may be prevented.

The light blocking member 230 may be disposed in the peripheral area PA under the second base substrate 210. The light blocking member 230 may prevent a circuit structure such as wires and driving circuits disposed in the peripheral area PA of the first substrate 100 from being viewed from outside of the display device 1000. The light blocking member 230 may prevent the light reflected from the circuit structure or the light emitted from the display area DA from being emitted in the front direction (e.g., the first direction D1) by passing through the peripheral area PA of the second base substrate 210.

The light blocking member 230 may include multiple light blocking layers. For example, the light blocking member 230 may include a first light blocking layer 232, a second light blocking layer 234, and a third light blocking layer 236. The first to third light blocking layers 232, 234, and 236 may extend in the second direction D2 and overlap each other in the first direction D1, in the second area BA under the second base substrate 210. Accordingly, the light blocking member 230 may effectively block light traveling in the first direction D1.

In an embodiment, the first light blocking layer 232 may be disposed on the lower surface of the second base substrate 210, the second light blocking layer 234 may be disposed on the lower surface of the first light blocking layer 232, and the third light blocking layer 236 may be disposed on the lower surface of the second light blocking layer 234. In other words, in the second area BA, the third light blocking layer 236 may be disposed on the lowermost portion of the light blocking member 230. However, the disclosure is not necessarily limited thereto. In another embodiment, in the second area BA, the first light blocking layer 232 may be disposed on the lowermost portion of the light blocking member 230. In still another embodiment, the second light blocking layer 234 may be disposed on the lowermost portion of the light blocking member 230.

In an embodiment, the first light blocking layer 232 and the blue color filter 220B may include a same material, the second light blocking layer 234 and the red color filter 220R may include a same material, and the third light blocking layer 236 and the green color filter 220G may include a same material. For example, the first light blocking layer 232 may be formed together with the blue color filter 220B, the second light blocking layer 234 may be formed together with the red color filter 220R, and the third light blocking layer 236 may be formed together with the green color filter 220G. For example, the first light blocking layer 232 may be a blue light blocking layer, the second light blocking layer 234 may be a red light blocking layer, and the third light blocking layer 236 may be a green light blocking layer.

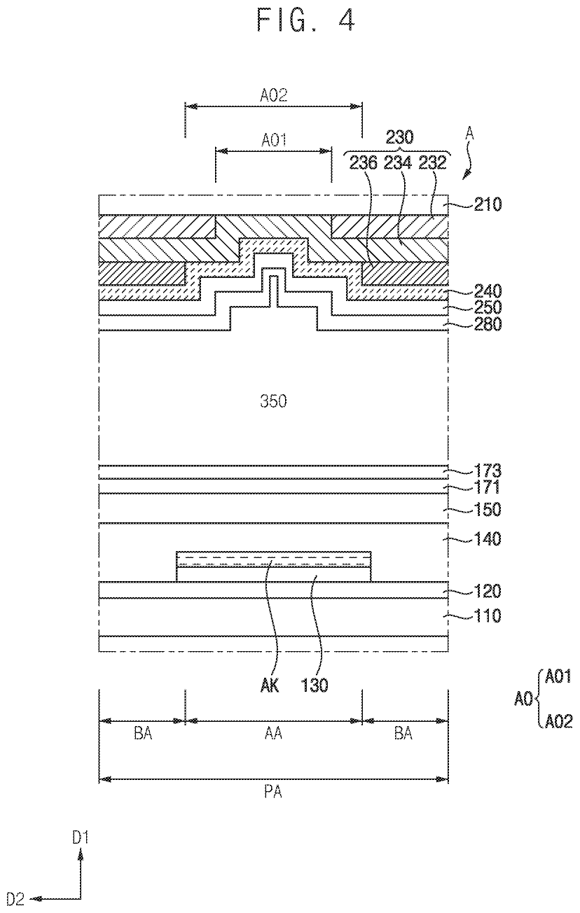

FIG. 4 is an enlarged view illustrating area ‘A’ of FIG. 3.

Referring to FIGS. 1 to 4, two of the first to third light blocking layers 232, 234, and 236 may define (or include) an opening AO located in the first area AA, and another one may cover at least one of the openings AO in the first area AA.

For example, as shown in FIGS. 3 and 4, among the first to third light blocking layers 232, 234, and 236, the first light blocking layer 232 and the third light blocking layer 236 may define the opening AO, and the second light blocking layer 234 may cover the opening AO in the first area AA. For example, the second light blocking layer 234 may cover the opening AO in the first area AA and extend in the second direction D2 to overlap the first light blocking layer 232 and the third light blocking layer 236 in the first direction D1.

In a plan view, the opening AO may overlap the align key AK of the first substrate 100. Accordingly, when the first substrate 100 and the second substrate 200 are bonded, it may be determined whether there is an alignment error by using the opening AO and the align key AK. For example, the opening AO may be an alignment opening for determining an alignment error between the first substrate 100 and the second substrate 200.

In an embodiment, the opening AO may include a first sub opening AO1 defined by one of the light blocking layers defining the opening AO and a second sub opening AO2 defined by another one of the light blocking layers defining the opening AO.

For example, as shown in FIGS. 3 and 4, the opening AO may include the first sub opening AO1 defined by the first light blocking layer 232 and the second sub opening AO2 defined by the third light blocking layer 236. For example, the first sub opening AO1 may pass through the first light blocking layer 232 and expose a portion of the second base substrate 210, and the second sub opening AO2 may pass through the third light blocking layer 236 and expose a portion of the second light blocking layer 234.

In an embodiment, in a cross-sectional view, a width of the first sub opening AO1 in the second direction D2 may be less than a width of the second sub opening AO2 in the second direction D2. For example, the inner surface of the opening AO may have a step.

Further, in a cross-sectional view, the width of the first sub opening AO1 in the second direction D2 and the width of the second sub opening AO2 in the second direction D2 may be less than a width of the align key AK in the second direction D2. In other words, the width of the opening AO in the second direction D2 may be less than the width of the align key AK in the second direction D2. Accordingly, when the first substrate 100 and the second substrate 200 are bonded, an alignment error between the first substrate 100 and the second substrate 200 may be determined more accurately.

According to embodiments, the opening AO may be covered by one of the first to third light blocking layers 232, 234, and 236. For example, as shown in FIGS. 3 and 4, the second light blocking layer 234 may cover the opening AO in the first area AA. Accordingly, visibility of the align key AK due to external light may be reduced. Therefore, after the first substrate 100 and the second substrate 200 are bonded, it is possible to prevent the align key AK from being recognized through the opening AO. Accordingly, the quality of the display device 1000 may be improved.

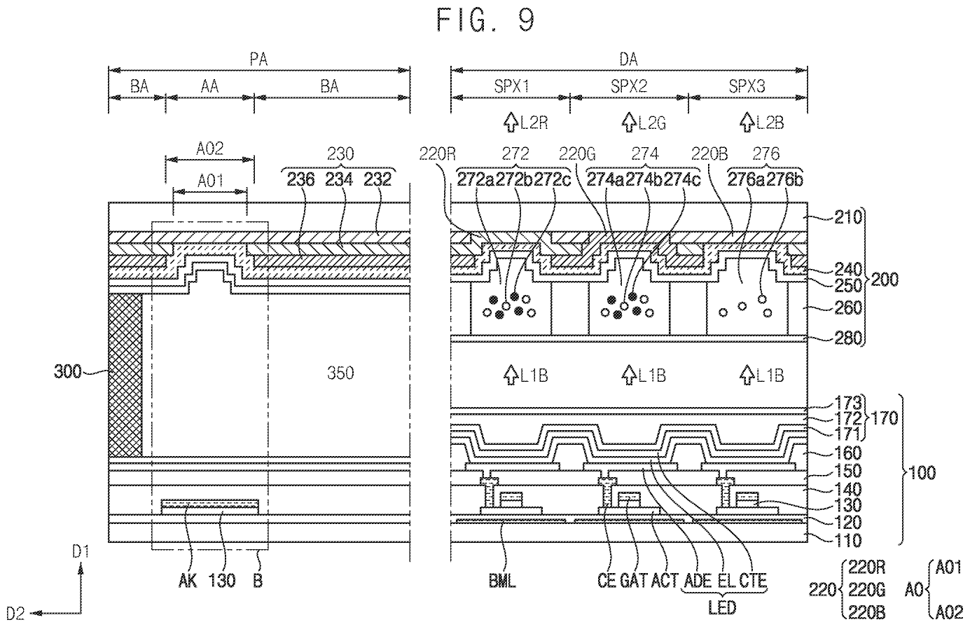

Although it is illustrated that the first light blocking layer 232 and the third light blocking layer 236 define the opening AO, and the second light blocking layer 234 cover the opening AO in FIGS. 3 and 4, the disclosure is not necessarily limited thereto. For example, the light blocking layers defining the opening AO and the light blocking layer covering the opening AO may be determined in various combinations. This will be described below in detail with reference to FIGS. 9 to 18.

The refraction layer 240 may be disposed under the color filter layer 220 and the light blocking member 230. For example, the refraction layer 240 may be disposed in an entire area of the display area DA and the peripheral area PA. For example, the refraction layer 240 may cover the color filter layer 220 in the display area DA and the light blocking member 230 in the peripheral area PA. The refraction layer 240 may control a path of light emitted from the lower portion. For example, the refraction layer 240 may change the path of obliquely incident light to the front direction (e.g., to the first direction D1). Accordingly, the refraction layer 240 may increase luminous efficiency of the display device 1000.

In an embodiment, the refraction layer 240 may include hollow particles. The hollow particles may be dispersed in a resin matrix. The hollow particles may include an inorganic material. For example, the hollow particle may include silica (SiO2), magnesium fluoride (MgF2), iron oxide (Fe3O4), or the like. These may be used alone or in combination with each other. The resin matrix may include an acrylic resin, a siloxane resin, a urethane resin, an imide resin, or the like, and may be selected in consideration of refractive index and process efficiency.

The first capping layer 250 may be disposed under the refraction layer 240. For example, the first capping layer 250 may be disposed in an entire area of the display area DA and the peripheral area PA. For example, the first capping layer 250 may cover the refraction layer 240. In an embodiment, the first capping layer 250 may include an inorganic insulating material.

The partition wall structure 260 may be disposed in the display area DA under the first capping layer 250. The partition wall structure 260 may form a space capable of accommodating an ink composition in the process of forming the first color conversion part 272, the second color conversion part 274, and the light transmission part 276. For example, the partition wall structure 260 may have a grid shape or a matrix shape in a plan view.

In an embodiment, the partition wall structure 260 may include an organic material. In an embodiment, the partition wall structure 260 may include a light blocking material. For example, at least a portion of the partition wall structure 260 may include a light blocking material such as black pigment, dye, or carbon black.

The first color conversion part 272, the second color conversion part 274, and the light transmission part 276 may be disposed in the display area DA under the first capping layer 250. For example, the first color conversion part 272, the second color conversion part 274, and the light transmission part 276 may be respectively disposed within the space define by the partition wall structure 260. The first color conversion part 272 may be disposed in the first sub-pixel SPX1, the second color conversion part 274 may be disposed in the second sub-pixel SPX2, and the light transmission part 276 may be disposed in the third sub-pixel SPX3.

The first color conversion part 272 may convert incident light L1B (e.g., blue light) emitted from the light emitting device LED into first transmitted light L2R having a first color. For example, the first color conversion part 272 may convert the blue incident light L1B to emit red first transmitted light L2R. Blue light not converted by the first color conversion part 272 may be blocked by the red color filter 220R. In an embodiment, the first color conversion part 272 may include a resin part 272a, a scatter 272b, and a wavelength conversion particle 272c.

The scatter 272b may increase an optical path by scattering the incident light L1B without substantially changing the wavelength of the incident light L1B incident to the first color conversion part 272. The scatter 272b may include a metal oxide or an organic material. In another embodiment, the scatter 272b may be omitted.

In an embodiment, the wavelength conversion particle 272c may include a quantum dot. The quantum dot may be defined as a semiconductor material having nanocrystals. The quantum dot may have a specific band gap depending on its composition and size. Accordingly, the quantum dots may absorb incident light and emit light having a different wavelength from that of the incident light. For example, the quantum dot may have a diameter of less than or equal to about 100 nm. For example, the quantum dot may have a diameter in a range of about 1 nm to about 20 nm. For example, the wavelength conversion particle 272c of the first color conversion part 272 may include quantum dot that absorbs blue light and emits red light.

The scatter 272b and the wavelength conversion particle 272c may be disposed in the resin part 272a. For example, the resin part 272a may include an epoxy-based resin, an acrylic-based resin, a phenol-based resin, a melamine-based resin, a cardo-based resin, an imide-based resin, or the like.

The second color conversion particle 274 may convert the incident light L1B emitted from the light emitting device LED into second transmitted light L2G having a second color. For example, the second color conversion part 274 may convert the blue incident light L1B to emit green second transmitted light L2G. Blue light not converted by the second color conversion part 274 may be blocked by the green color filter 220G. In an embodiment, the second color conversion part 274 may include a resin part 274a, a scatter 274b, and a wavelength conversion particle 274c.

The resin part 274a and the scatter 274b of the second color conversion part 274 may be substantially the same as or similar to the resin part 272a and the scatter 272b of the first color conversion part 272. For example, the wavelength conversion particle 274c of the second color conversion part 274 may include a quantum dot that absorbs blue light and emits green light.

The light transmission part 276 may transmit the incident light L1B emitted from the light emitting device LED. For example, the light transmission part 276 may emit third transmitted light L2B having a wavelength substantially the same as the wavelength of the blue incident light L1B. In an embodiment, the light transmission part 276 may include a resin part 276a and a scatter 276b. The resin part 276a and the scatter 276b of the light transmission part 276 may be substantially the same as or similar to the resin part 272a and the scatter 272b of the first color conversion part 272.

The second capping layer 280 may be disposed under the first capping layer 250, the partition wall structure 260, the first color conversion part 272, the second color conversion part 274, and the light transmission part 276. For example, the second capping layer 280 may be disposed in an entire area of the display area DA and the peripheral area PA. For example, the second capping layer 280 may cover the partition wall structure 260, the first color conversion part 272, the second color conversion part 274, and the light transmission part 276 in the display area DA, and cover the first capping layer 250 in the peripheral area PA. In an embodiment, the second capping layer 280 may include a silicon compound.

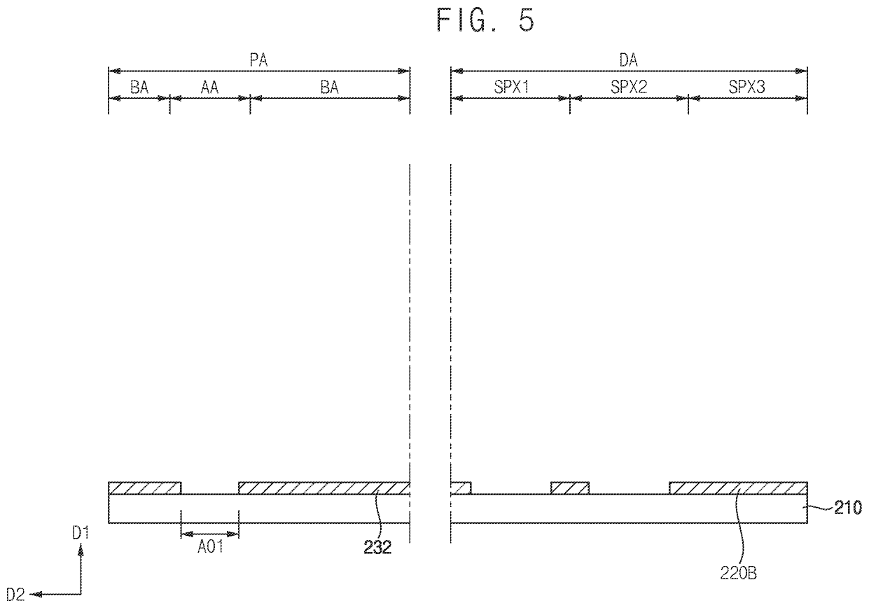

FIGS. 5 to 8 are schematic cross-sectional views illustrating a method of manufacturing a color conversion substrate included in the display device of FIG. 3.

Hereinafter, a manufacturing method of the second substrate 200 included in the display device 1000 of FIG. 3 will be briefly described with reference to FIGS. 5 to 8.

Referring to FIG. 5, the blue color filter 220B may be formed in the display area DA on the second base substrate 210 and the first light blocking layer 232 may be formed on the second base substrate 210 in the peripheral area PA. The first light blocking layer 232 may be formed to surround the display area DA in the peripheral area PA in a plan view. In an embodiment, the blue color filter 220B and the first light blocking layer 232 may be formed substantially simultaneously. For example, the blue color filter 220B and the first light blocking layer 232 may include a same material. The first light blocking layer 232 may be a blue light blocking layer.

In an embodiment, the first light blocking layer 232 may define the first sub opening AO1. In an embodiment, the first sub opening AO1 may be formed by patterning a portion of the first light blocking layer 232 by adjusting the transmission area and the non-transmission area of an exposure mask in the process of forming the first light blocking layer 232.

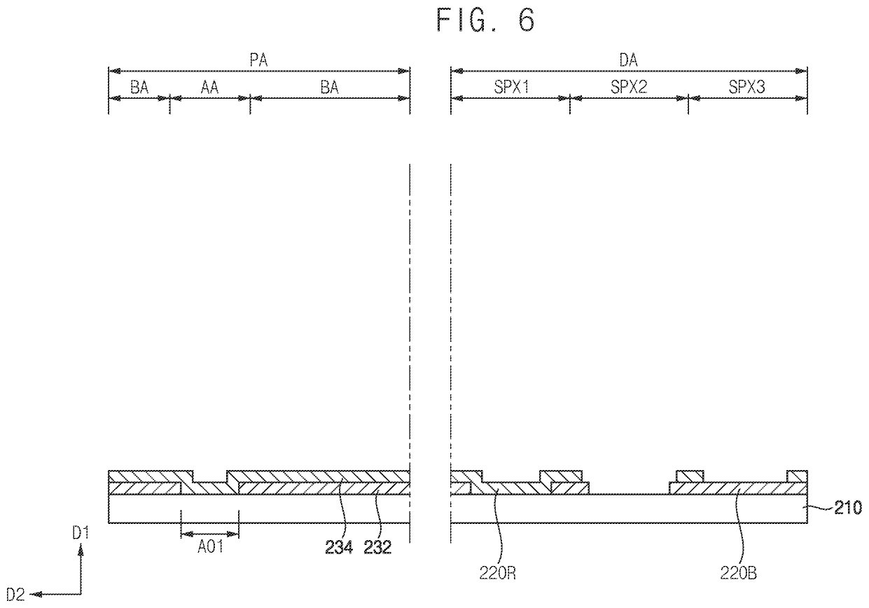

Referring to FIG. 6, the red color filter 220R may be formed in the display area DA on the second base substrate 210 and the second light blocking layer 234 may be formed on the second base substrate 210 in the peripheral area PA. The second light blocking layer 234 may be formed to surround the display area DA in the peripheral area PA in a plan view. In an embodiment, the red color filter 220R and the second light blocking layer 234 may be formed substantially simultaneously. For example, the red color filter 220R and the second light blocking layer 234 may include a same material. The second light blocking layer 234 may be a red light blocking layer. The second light blocking layer 234 may fill the first sub opening AO1. For example, the second light blocking layer 234 may cover the first sub opening AO1 in the first area AA and extend in the second direction D2 to overlap the first light blocking layer 232 in the first direction DR1 in the second area BA.

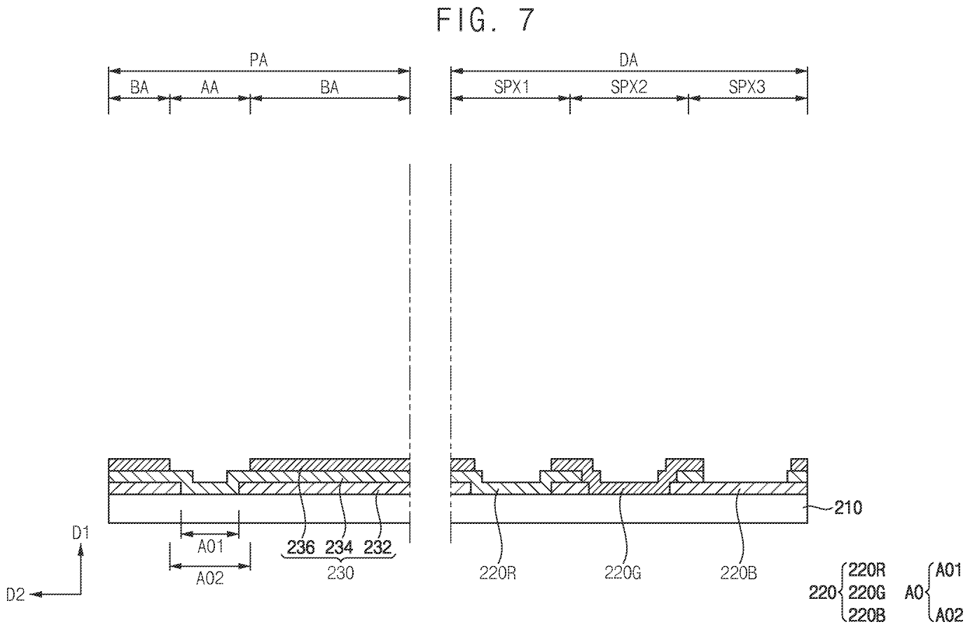

Referring to FIG. 7, the green color filter 220G may be formed in the display area DA on the second base substrate 210 and a third light blocking layer 236 may be formed on the second base substrate 210 in the peripheral area PA. The third light blocking layer 236 may be formed to surround the display area DA in the peripheral area PA in a plan view. In an embodiment, the green color filter 220G and the second light blocking layer 234 may be formed substantially simultaneously. For example, the green color filter 220G and the third light blocking layer 236 may include a same material. The third light blocking layer 236 may be a green light blocking layer.

In an embodiment, the third light blocking layer 236 may define the second sub opening AO2. In an embodiment, the second sub opening AO2 may be formed by patterning a portion of the third light blocking layer 236 by adjusting the transmission area and the non-transmission area of an exposure mask in the process of forming the third light blocking layer 236. The first sub opening AO1 and the second sub opening AO2 may constitute the opening AO.

The second sub opening AO2 may overlap a portion of the second light blocking layer 234 in the first area AA in the first direction D1. Accordingly, the second sub opening AO2 may be covered by the second light blocking layer 234. For example, the second light blocking layer 234 may cover the second sub opening AO2 in the first area AA, and extend in the second direction D2 to overlap the first light blocking layer 232 and the third light blocking layer 236 in the first direction D1 in the second area BA.

Accordingly, the first light blocking layer 232 and the third light blocking layer 236 may be formed to define the opening AO located in the first area AA, and the second light blocking layer 234 may cover the opening AO in the first area AA.

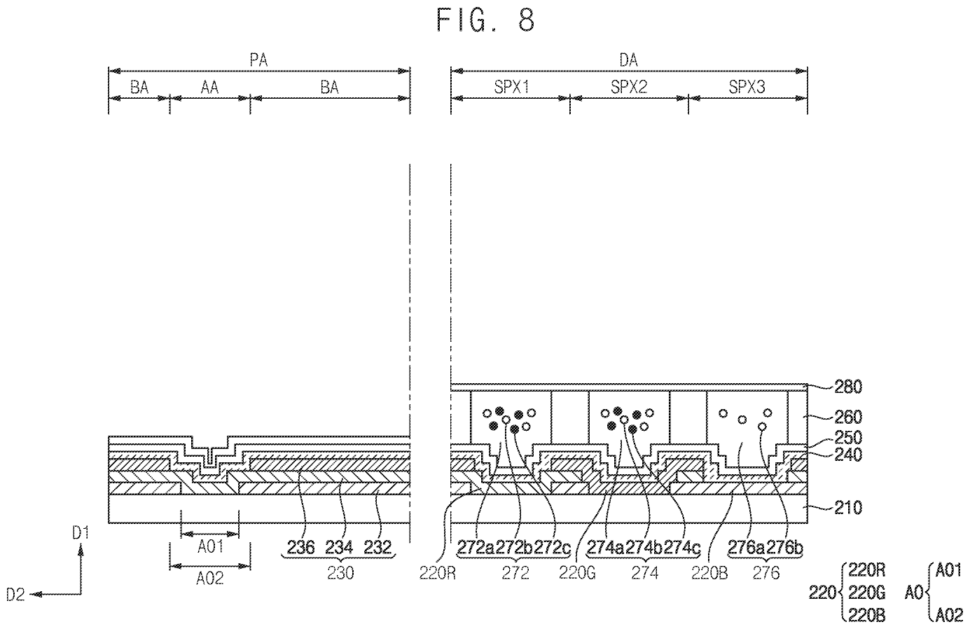

Referring to FIG. 8, the refraction layer 240 may be formed in the display area DA and the peripheral area PA on the second base substrate 210. The refraction layer 240 may be formed to cover the color filter layer 220 and the light blocking member 230. The first capping layer 250 may be formed in the display area DA and the peripheral area PA on the second base substrate 210. The first capping layer 250 may be formed to cover the refraction layer 240. The partition wall structure 260 may be formed in the display area DA on the first capping layer 250. Spaces for forming the first color conversion part 272, the second color conversion part 274, and the light transmission part 276 may be formed by the partition wall structure 260. The first color conversion part 272, the second color conversion part 274, and the light transmission part 276 may be respectively formed in the space defined by the partition wall structure 260. The second capping layer 280 may be formed in the display area DA on the partition wall structure 260, the first color conversion unit 272, the second color conversion unit 274, and the light transmission unit 276 and in the peripheral area PA on the first capping layer 250. The second capping layer 280 may be formed to cover the partition wall structure 260, the first color conversion part 272, the second color conversion part 274, the light transmission part 276, and the first capping layer 250.

FIGS. 9 to 18 are schematic cross-sectional views illustrating display devices according to other embodiments.

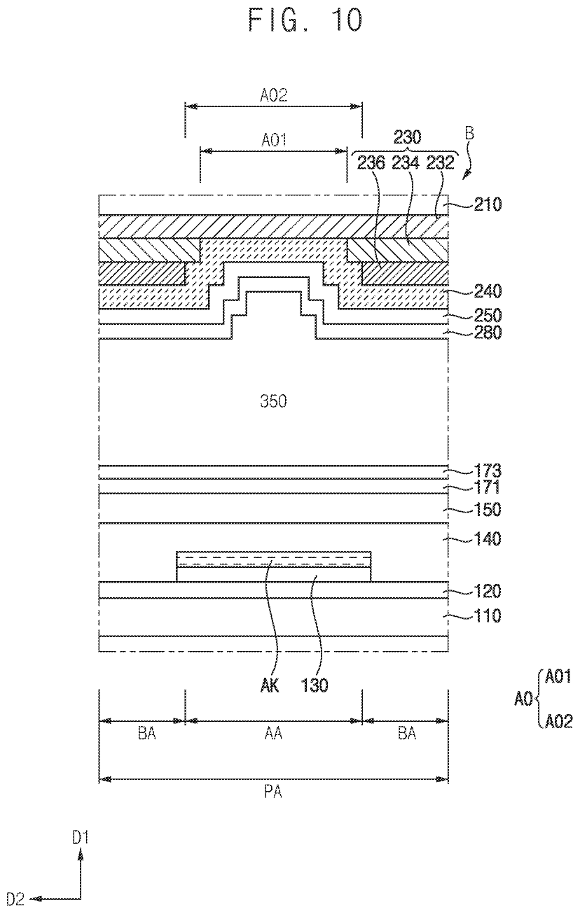

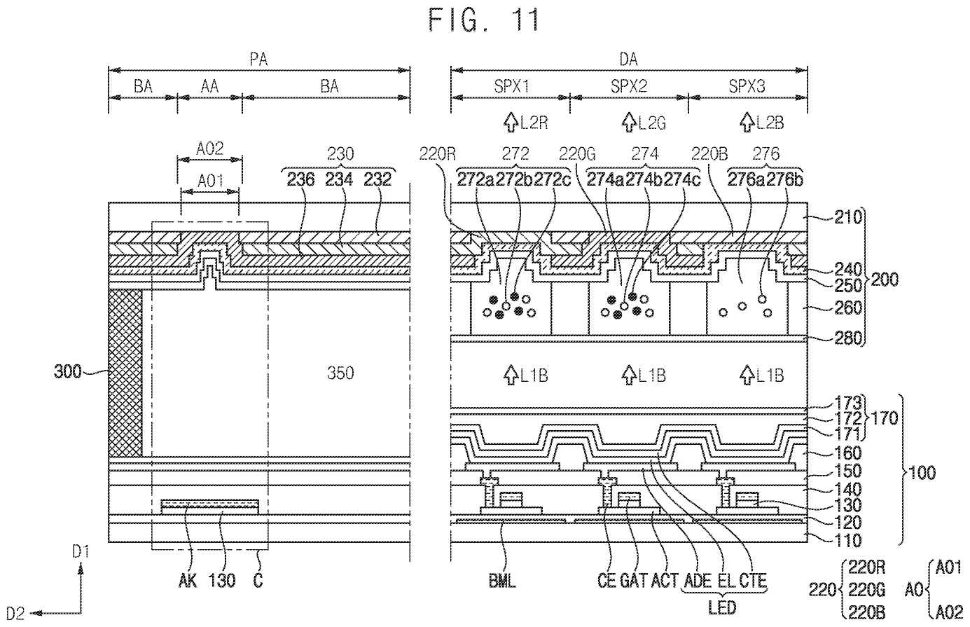

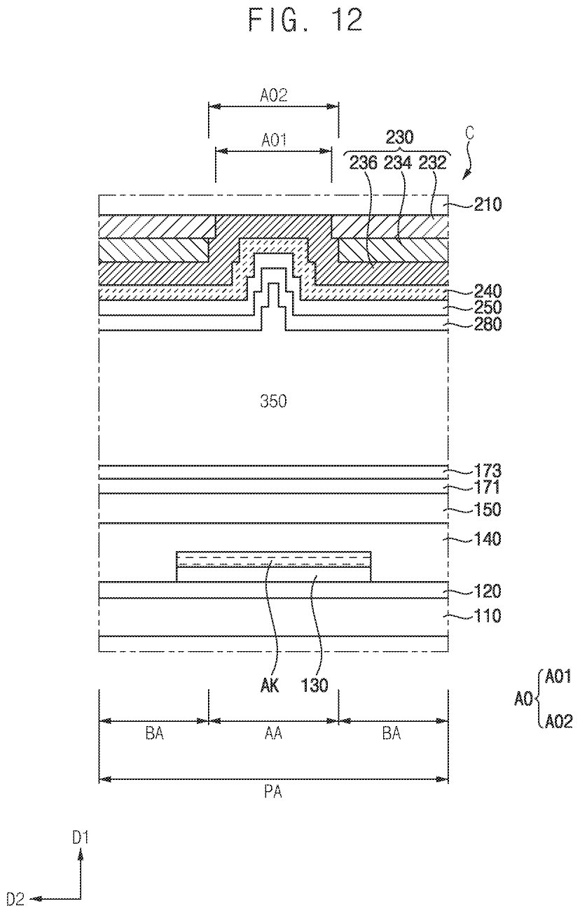

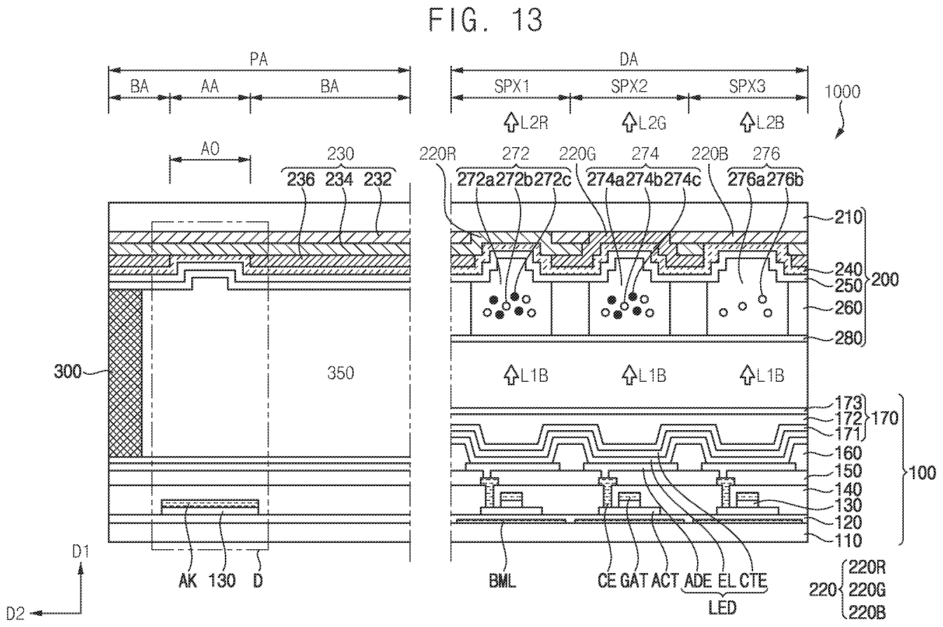

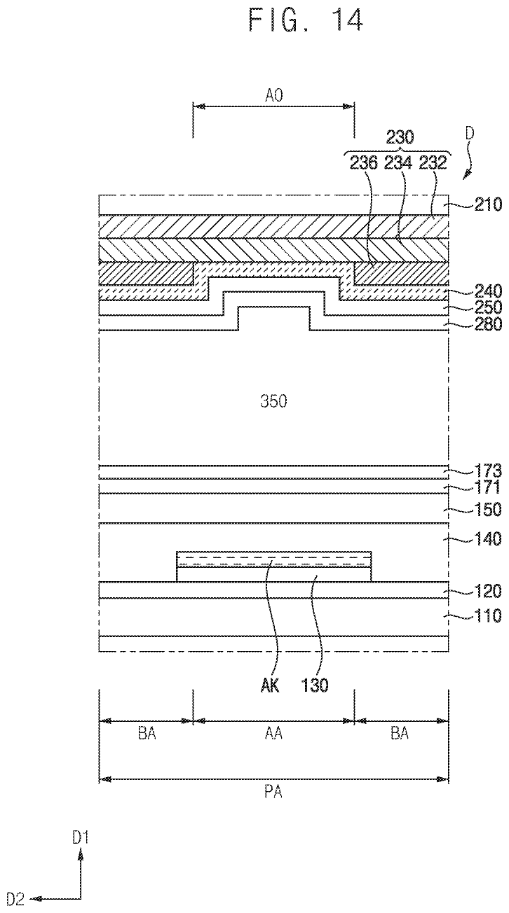

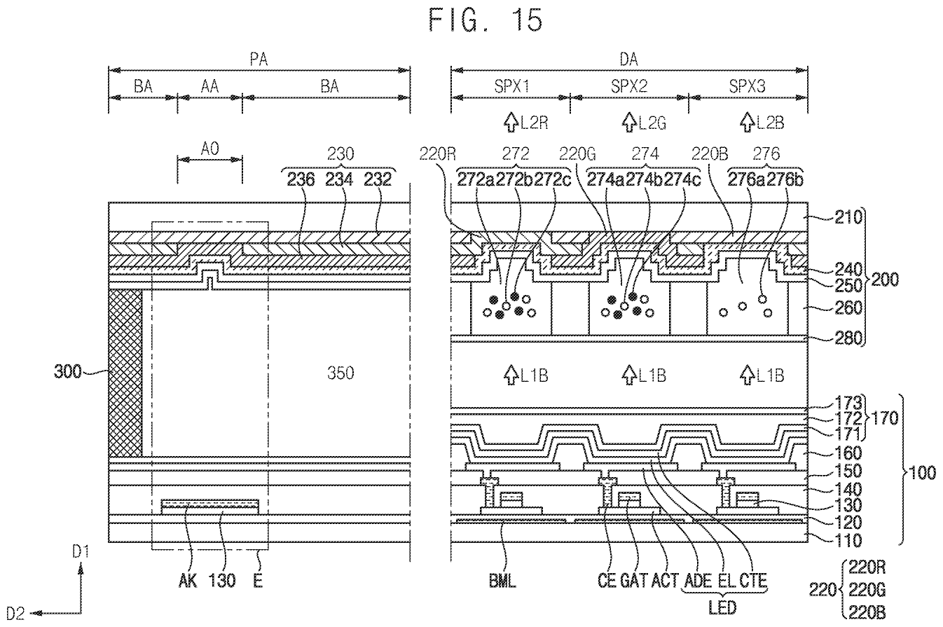

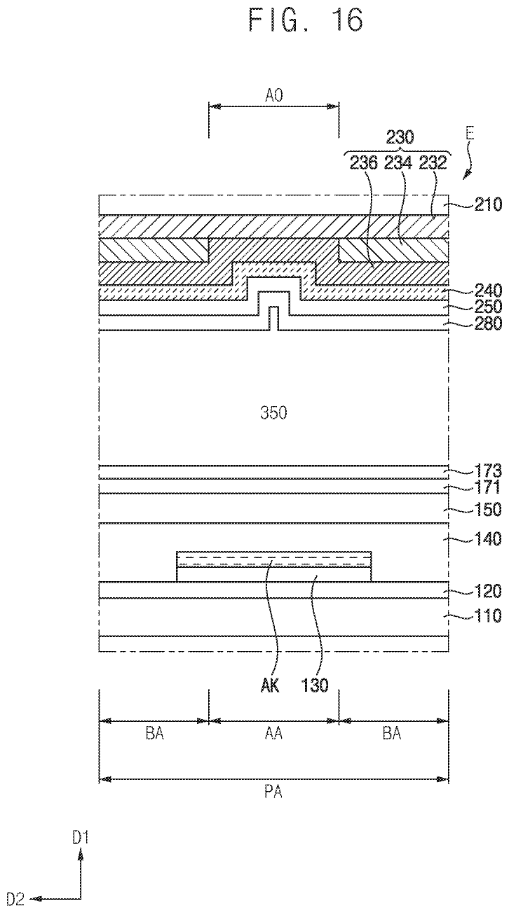

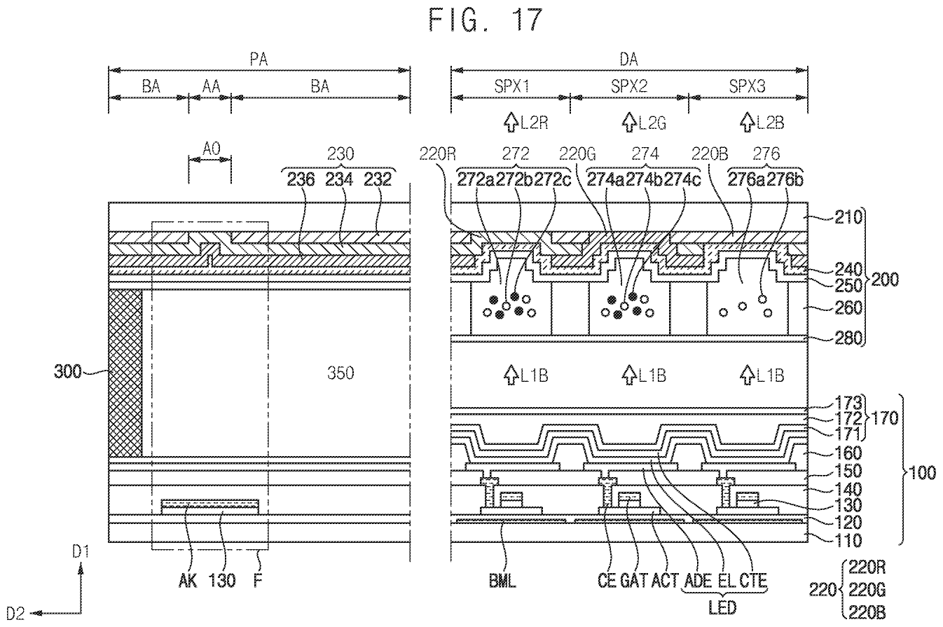

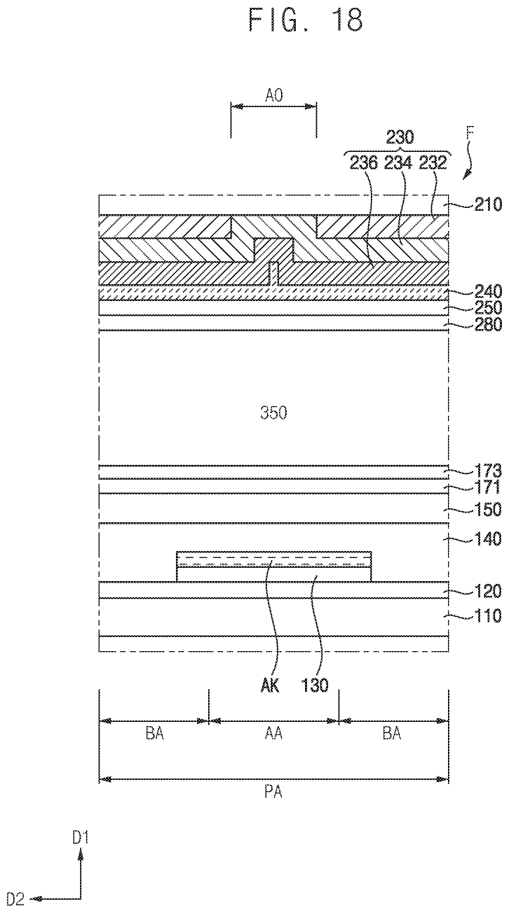

For example, FIGS. 9, 11, 13, 15, and 17 may correspond to the cross-sectional view of FIG. 3. FIG. 10 may be an enlarged view illustrating area ‘B’ of FIG. 9. FIG. 12 may be an enlarged view illustrating area the ‘C’ of FIG. 11. FIG. 14 may be an enlarged view illustrating area ‘D’ of FIG. 13. FIG. 16 may be an enlarged view illustrating area ‘E’ of FIG. 15. FIG. 18 may be an enlarged view illustrating area ‘F’ of FIG. 17. In the following description, differences from the display device described with reference to FIGS. 3 and 4 will be described, and overlapping descriptions will be omitted or simplified.

Referring to FIGS. 9 and 10, in an embodiment, among the first to third light blocking layers 232, 234, and 236, the second light blocking layer 234 and the third light blocking layer 236 may define the opening AO located in the first area AA, and the first light blocking layer 232 may cover the opening AO in the first area AA. For example, the first light blocking layer 232 may cover the opening AO in the first area AA and extend in the second direction D2 to overlap the second light blocking layer 234 and the third light blocking layer 236 in the first direction D1 in the second area BA.

The first sub opening AO1 may be defined by the second light blocking layer 234, and the second sub opening AO2 may be defined by the third light blocking layer 236. For example, the first sub opening AO1 may pass through the second light blocking layer 234 and expose a portion of the first light blocking layer 232, and the second sub opening AO2 may pass through the third light blocking layer 236 and expose a portion of the first light blocking layer 232 and a portion of the second light blocking layer 234.

Referring to FIGS. 11 and 12, in an embodiment, among the first to third light blocking layers 232, 234, and 236, the first light blocking layer 232 and the second light blocking layer 234 may define the opening AO located in the first area AA, and the third light blocking layer 236 may cover the opening AO in the first area AA. For example, the third light blocking layer 236 may cover the opening AO in the first area AA and extend in the second direction D2 to overlap the first light blocking layer 232 and the second light blocking layer 234 in the first direction D1 in the second area BA.

The first sub opening AO1 may be defined by the first light blocking layer 232, and the second sub opening AO2 may be defined by the second light blocking layer 234. For example, the first sub opening AO1 may pass through the first light blocking layer 232 and expose a portion of the second base substrate 210, and the second sub opening AO2 may pass through the second light blocking layer 234 and expose a portion of the second base substrate 210 and a portion of the first light blocking layer 232.

Referring to FIGS. 13 to 18, in embodiments, one of the first to third light blocking layers 232, 234, and 236 may define the opening AO located in the first area AA, and other two may cover the opening AO in the first area AA.

For example, among the first to third light blocking layers 232, 234, and 236, the third blocking layer 236 may define the opening AO located in the first area AA, and the first light blocking layer 232 and the second blocking layer 234 may cover the opening AO in the first area AA. For example, the first light blocking layer 232 and the second light blocking layer 234 may cover the opening AO in the first area AA and extend in the second direction D2 to overlap the third light blocking layer 236 in the first direction D1 in the second area BA. The opening AO may pass through the third light blocking layer 236 and expose a portion of the second blocking layer 234.

In an embodiment, in a cross-sectional view, the width of the opening AO in the second direction D2 may be less than a width of the align key AK in the second direction D2. Accordingly, when the first substrate 100 and the second substrate 200 are bonded, an alignment error between the first substrate 100 and the second substrate 200 may be determined more accurately.

Although it is illustrated that the third light blocking layer 236 define the opening AO located in the first area AA, and the first light blocking layer 232 and the second light blocking layer 234 cover the opening AO in FIGS. 13 and 14, the disclosure is not necessarily limited thereto. For example, the light blocking layer defining the opening AO and the light blocking layers covering the opening AO may be determined in various combinations.

For example, in another embodiment, as shown in FIGS. 15 and 16, among the first to third light blocking layers 232, 234, and 236, the second blocking layer 234 may define the opening AO located in the first area AA, and the first light blocking layer 232 and the third blocking layer 236 may cover the opening AO in the first area AA. For example, the first light blocking layer 232 and the third light blocking layer 236 may cover the opening AO in the first area AA and extend in the second direction D2 to overlap the second light blocking layer 234 in the first direction D1 in the second area BA. The opening AO may pass through the second light blocking layer 234 and expose a portion of the first blocking layer 232.

In still another embodiment, as shown in FIGS. 17 and 18, among the first to third light blocking layers 232, 234, and 236, the first blocking layer 232 may define the opening AO located in the first area AA, and the second light blocking layer 234 and the third blocking layer 236 may cover the opening AO in the first area AA. For example, the second light blocking layer 234 and the third light blocking layer 236 may cover the opening AO in the first area AA and extend in the second direction D2 to overlap the first light blocking layer 234 in the first direction D1 in the second area BA. The opening AO may pass through the first light blocking layer 234 and expose a portion of the second base substrate 210.

According to embodiments, the opening AO may be covered by two of the first to third light blocking layers 232, 234, and 236. Accordingly, visibility of the align key AK due to external light may be further reduced. Therefore, after the first substrate 100 and the second substrate 200 are bonded, it is possible to further prevent the align key AK from being recognized through the opening AO. Accordingly, a quality of the display device 1000 may be further improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A color conversion substrate comprising:
a base substrate including:
a display area; and
a peripheral area disposed adjacent to the display area and including a first area and a second area surrounding the first area;
a color filter layer disposed in the display area under the base substrate; and
a light blocking member disposed in the peripheral area under the base substrate and including a first light blocking layer, a second light blocking layer, and a third light blocking layer overlapping each other in a first direction which is a thickness direction of the base substrate in the second area, wherein
two of the first to third light blocking layers include an opening in the first area, and
another one of the first to third light blocking layers covers at least one of the openings in the first area.

2. The color conversion substrate of claim 1, wherein
the color filter layer includes a red color filter that selectively transmits red light, a green color filter that selectively transmits green light, and a blue color filter that selectively transmits blue light,
the first light blocking layer and the blue color filter include a same material,
the second light blocking layer and the red color filter include a same material, and
the third light blocking layer and the green color filter include a same material.

3. The color conversion substrate of claim 2, wherein
each of the first light blocking layer and the third light blocking layer includes the opening, and
the second light blocking layer covers the openings in the first area.

4. The color conversion substrate of claim 2, wherein
each of the second light blocking layer and the third light blocking layer includes the opening, and
the first light blocking layer covers the openings in the first area.

5. The color conversion substrate of claim 2, wherein
each of the first light blocking layer and the second light blocking layer includes the opening, and
the third light blocking layer covers the openings in the first area.

6. The color conversion substrate of claim 1, wherein the opening includes:
a first sub opening disposed on one of the first to third light blocking layers including the opening; and
a second sub opening disposed on another one of the first to third light blocking layers including the opening.

7. The color conversion substrate of claim 6, wherein, in a cross-sectional view, a width of the first sub opening in a second direction perpendicular to the first direction is less than a width of the second sub opening in the second direction.

8. The color conversion substrate of claim 1, further comprising:
a refraction layer covering the color filter layer and the light blocking member;
a first capping layer disposed on a lower surface of the refraction layer; and
a second capping layer disposed on a lower surface of the first capping layer in the peripheral area.

9. A color conversion substrate comprising:
a base substrate including:
a display area; and
a peripheral area disposed adjacent to the display area and including a first area and a second area surrounding the first area;
a color filter layer disposed in the display area under the base substrate; and
a light blocking member disposed in the peripheral area under the base substrate and including a first light blocking layer, a second light blocking layer, and a third light blocking layer overlapping each other in a first direction which is a thickness direction of the base substrate in the second area, wherein
one of the first to third light blocking layers includes an opening in the first area, and
at least another one of the first to third light blocking layers covers the opening in the first area.

10. The color conversion substrate of claim 9, wherein
the color filter layer includes a red color filter that selectively transmits red light, a green color filter that selectively transmits green light, and a blue color filter that selectively transmits blue light,
the first light blocking layer and the blue color filter include a same material,
the second light blocking layer and the red color filter include a same material, and
the third light blocking layer and the green color filter include a same material.

11. The color conversion substrate of claim 10, wherein
the first light blocking layer includes the opening, and
the second light blocking layer and the third light blocking layer overlap each other in the first direction in the first area and cover the opening.

12. The color conversion substrate of claim 10, wherein
the second light blocking layer includes the opening, and
the first light blocking layer and the third light blocking layer overlap each other in the first direction in the first area and cover the opening.

13. The color conversion substrate of claim 10, wherein
the third light blocking layer includes the opening, and
the first light blocking layer and the second light blocking layer overlap each other in the first direction in the first area and cover the opening.

14. A display device comprising:
a display substrate including a first base substrate and pixels disposed on the first base substrate;
a color conversion substrate facing the display substrate; and
a sealing member bonding the display substrate and the color conversion substrate, wherein
the color conversion substrate includes:
a second base substrate including:
a display area; and
a peripheral area disposed adjacent to the display area and including a first area and a second area surrounding the first area;
a color filter layer disposed in the display area under the second base substrate; and
a light blocking member disposed in the peripheral area under the second base substrate and including a first light blocking layer, a second light blocking layer, and a third light blocking layer overlapping each other in a first direction which is a thickness direction of the second base substrate in the second area,
at least one of the first to third light blocking layers includes an opening in the first area, and
at least another one of the first to third light blocking layers covers the opening in the first area.

15. The display device of claim 14, wherein
the color filter layer includes a red color filter that selectively transmits red light, a green color filter that selectively transmits green light, and a blue color filter that selectively transmits blue light,
the first light blocking layer and the blue color filter include a same material,
the second light blocking layer and the red color filter include a same material, and
the third light blocking layer and the green color filter include a same material.

16. The display device of claim 14, wherein the display substrate further includes an align key disposed on the first base substrate and overlapping the opening in the first direction.

17. The display device of claim 16, wherein, in a cross-sectional view, a width of the opening in a second direction perpendicular to the first direction is greater than a width of the align key in the second direction.

18. The display device of claim 16, wherein the opening and the align key are spaced apart from the sealing member in a plan view.

19. The display device of claim 16, wherein the align key includes a metal.

20. The display device of claim 14, further comprising:
a filling layer disposed between the display substrate and the color conversion substrate.
